(19) United States
(12) Patent Application Publication
(10) Pub. No.: US 2025/0349378 A1
(43) Pub. Date: Nov. 13, 2025

(54) REDUCING READ OPERATIONS DURING READ ERROR HANDLING IN A MEMORY DEVICE

(71) Applicant: Micron Technology, Inc., Boise, ID (US)

(72) Inventors: Patrick R. Khayat, San Diego, CA (US); Jeffery S. McNeil, Boise, ID (US); Dung Viet Nguyen, San Jose, CA (US)

(21) Appl. No.: 19/203,401

(22) Filed: May 9, 2025

Related U.S. Application Data
(60) Provisional application No. 63/644,650, filed on May 9, 2024.

(51) Int. Cl. G11C 29/12

(52) U.S. Cl. CPC G11C 29/12005

(57) ABSTRACT

A plurality of read operations is performed on encoded host data stored in a memory device using the plurality of read voltage level adjustments to obtain current sensed data responsive to initiating an auto-read calibration operation comprising a plurality of read voltage level adjustments. A previous sensed data is obtained from a previous one of the plurality of read operations performed on the encoded host data using a previous read voltage level adjustment. One or more flipped bits of the current sensed data is identified based on the previous sensed data and the current sensed data. A likelihood value is assigned to the one or more flipped bits. Soft-decision decoding is performed on the encoded host data responsive to completion of the auto-read calibration, performing, using the assigned likelihood value.

### RELATED APPLICATIONS

T his application claims the benefit of U.S. Provisional Patent Application No. 63/644,650, filed May 9, 2024, which is incorporated by reference herein.

### TECHNICAL FIELD

Embodiments of the disclosure relate generally to memory sub-systems, and more specifically, relate to reducing read operations during read error handling in a memory device of a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1A illustrates an example computing system that includes a memory sub-system in accordance with some embodiments of the present disclosure.

FIG. 1B is a block diagram of memory device(s) in communication with a memory sub-system controller of a memory sub-system, in accordance with some embodiments of the present disclosure.

FIG. 2 is a diagram illustrating an auto read calibration on a programming voltage distributions for a memory device in accordance with some embodiments of the present disclosure.

FIG. 3 illustrates an example of a table storing LLR values assigned to bits of a sensed data for use in reducing read operations during read error handling, in accordance with some embodiments of the present disclosure.

FIG. 4 is a flow diagram of an example method to reducing read operations during read error handling in a memory device, in accordance with some embodiments of the present disclosure.

FIG. 5 is a block diagram of an example computer system in which embodiments of the present disclosure may operate.

### DETAILED DESCRIPTION

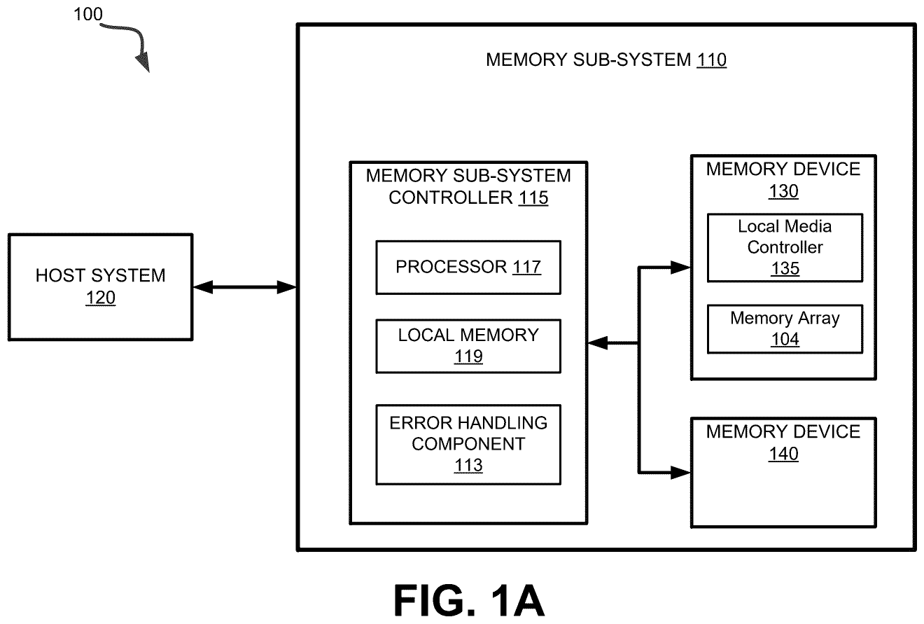

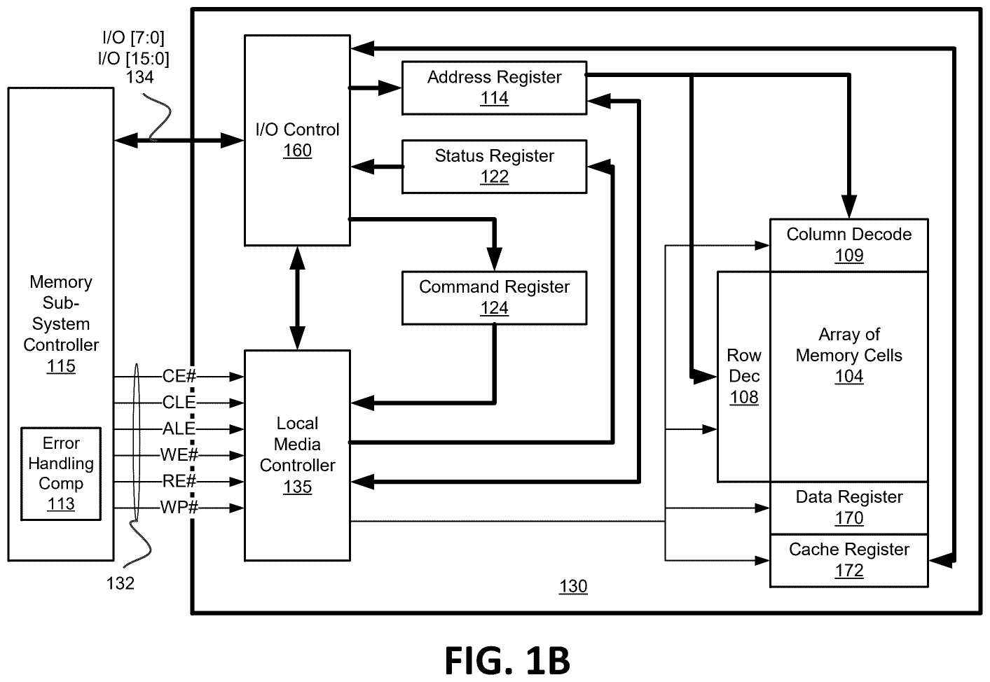

Aspects of the present disclosure are directed to reducing read operations during read error handling in a memory device of a memory sub-system. A memory sub-system can be a storage device, a memory module, or a combination of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system may utilize one or more memory devices, including any combination of the different types of non-volatile memory devices and/or volatile memory devices, to store the data provided by the host system. In some implementations, a memory sub-system may be represented by a solid-state drive (SSD), which may include one or more non-volatile memory devices. In some implementations, the non-volatile memory devices may be provided by negative-and (NAND) type flash memory devices. Other examples of non-volatile memory devices are described below in conjunction with FIG. 1A. A non-volatile memory device is a package of one or more dice. Each die may include one or more planes. A plane is a portion of a memory device that includes multiple memory cells. Some memory devices may include two or more planes. For some types of non-volatile memory devices (e.g., NAND devices), each plane includes a set of physical blocks. Each block includes a set of pages. “Block” herein shall refer to a set of contiguous or non-contiguous memory pages. A “block” may refer to a unit of the memory device used to store data and may include a group of memory cells. An example of a “block” is an “erasable block,” which is the minimal erasable unit of memory, while “page” is a minimal writable unit of memory. Each page includes a set of memory cells. A memory cell is an electronic circuit that stores information.

A memory device may include multiple memory cells arranged in a two-dimensional grid. The memory cells are formed onto a silicon wafer in an array of columns and rows. A memory cell includes a capacitor that holds an electric charge and a transistor that acts as a switch controlling access to the capacitor. Accordingly, the memory cell may be programmed (written to) by applying a certain voltage, which results in an electric charge being held by the capacitor. The memory cells are joined by wordlines, which are conducting lines electrically connected to the control gates of the memory cells, and bitlines, which are conducting lines electrically connected to the drain electrodes of the memory cells.

Depending on the cell type, each memory cell may store one or more bits of binary information and has various logic states that correlate to the number of bits being stored. The logic states may be represented by binary values, such as “0” and “1”, or combinations of such values. A memory cell may be programmed (written to) by applying a certain voltage to the memory cell, which results in an electric charge being held by the memory cell, thus allowing modulation of the voltage distributions produced by the memory cell. A set of memory cells referred to as a memory page may be programmed together in a single operation, e.g., by selecting consecutive bitlines.

Precisely controlling the amount of the electric charge stored by the memory cell allows establishing multiple logical levels, thus effectively allowing a single memory cell to store multiple bits of information. A read operation may be performed by comparing the measured threshold voltages (Vt) exhibited by the memory cell to one or more reference voltage levels in order to distinguish between two logical levels for single-level cell (SLCs) and between multiple logical levels for multi-level cells. Each logical level may be translated into a corresponding binary representation of the content of the memory cell. In an illustrative example, a gray code may be employed for translating the cell charge levels (voltage levels) into their respective binary representations and vice versa. A gray code refers to an encoding in which adjacent numbers have a single digit different by one.

Memory access operations (e.g., a read operation, a programming (write) operation, an erase operation, etc.) may be executed with respect to sets of the memory cells, e.g., in response to receiving memory access commands from the host. A memory access operation may specify the requested memory access operation (e.g., write, erase, read, etc.) and a logical address, which the memory sub-system would translate to a physical address identifying a set of memory cells (e.g., a block).

In order to improve endurance of a memory device, the data to be written to the memory device may be modulated to achieve a desired distribution of the charge levels in the memory cells addressable by a given wordline and, in some implementations, also in the memory cells addressable by neighboring wordlines of the given wordline. For example, a random data pattern encoded by a gray code would result in uniform distribution of the memory cell charge levels (such that the number of memory cells at an arbitrary chosen charge level being roughly equal to the number of memory cells at any other charge level).

The modulated data may be encoded prior to being stored on a memory device, and thus would need to be decoded when later retrieved from the memory sub-system. For example, a sequence of symbols (e.g., representing one or more bits of binary information), may be transformed by an encoder to generate a codeword, which may then be stored on a memory device. However, in some cases, the sensed data read back from the memory device may differ from the original encoded data, e.g., on account of errors (e.g., bit-flip errors) that may have occurred during storage and/or retrieval of the encoded data to/from the memory device.

In some implementations, the data may be encoded using an error correcting code (ECC), which produces encoded data that includes redundant information allowing the original data to be recovered even if some errors have been introduced during the data storage and/or retrieval. Accordingly, the transformation employed by the encoder may be chosen such that the errors (e.g., bit flips that may occur when storing and/or retrieving the codeword) may be detected and corrected when the codeword is later retrieved from the memory device thereof.

One class of ECCs that may be used are linear codes, which may be characterized by a set of linearly independent relationships. For example, a linear code having codewords of length N, which may carry K information symbols and (N-K) (or M) parity-check symbols, in general, may be characterized by (N-K) linear relationships. Linear codes may be defined by a parity-check matrix, which may describe the linear relationships that elements of a valid codeword must satisfy. Each row of a parity-check matrix, for example, may describe a separate linear relationship that a valid codeword must satisfy (e.g., requiring the weighted sum of specific elements of the codeword to equal zero), with the value in each column indicating a weight that a particular element is given in the relationship. For instance, each row of a parity-check matrix that defines a binary linear code may require the modulo-2 sum of specific bits of a codeword, which may be given a column weight of ‘1’ (and all other bits ‘0’), to be equal to zero.

Low density parity check (LDPC) codes are a family of linear codes that has sparsely populated parity-check matrices (e.g., having a low density of non-zero symbols). A binary LDPC code having codewords of length N, comprising K bits of information and M parity-check bits, may be defined by a parity-check matrix of size M×N. Similarly, a non-binary LDPC code, in which each symbol of the non-binary alphabet represents s bits, may be defined by a parity-check matrix of size sM×sN.

A parity-check matrix that has M rows and N columns may define an LDPC code having codewords of length N that may carry K information bits and M parity bits. Each row of the parity-check matrix may describe a linear relationship that a valid codeword of the LDPC code must satisfy. For example, a row of the parity-check matrix may require a valid codeword to satisfy the relationship: bit-2 ⊕bit-6 ⊕bit-7 . . . bit-N-4-=0.

Data encoded using an LDPC code may be decoded using different techniques, which may vary in terms of the input they take and the error correction capabilities they provide. Hard-decision decoding techniques, for example, may rely on a “hard” input value of a received codeword (e.g., a singular determination as to whether each bit-value of a codeword is ‘0’ or ‘1’). A memory sub-system, for example, in retrieving a stored codeword from a memory device, may perform a read operation that makes a hard decision as to the value of each bit of the codeword (i.e., as being either ‘0’ or ‘1’) and returns a series of “hard bits.”

Should the decoder fail to correct one or more errors in the sensed data, the memory sub-system may perform read error handling in an attempt to recover the data. The read error handling may include one or more read error handling operations, such as read retries, coarse threshold estimation (CTE), auto read calibration (ARC), and soft-decision decoding (e.g., 1 hard bits (H)/2 soft bits (S) (1H2S)). Read retry is a process that uses different parameters, such as the read voltage, as compared to the previous read operation performed on the memory cell. Coarse threshold estimation (CTE) estimates a “coarse” read voltage level that differentiate between logical ‘0’ and ‘1’ in memory cells and performs adaptive read operation to adjust the read reference voltage to a level that is more likely to accurately distinguish between ‘0’s and ‘1’s given the current state of the memory cell. Auto read calibration (ARC) performs read voltage level adjustments based on values of one or more data state metrics obtained from a sequence of read and/or write operations. In an illustrative example, the data state metric refers to a population of non-conducting cells (cells having threshold voltage higher than a read strobe).

In some implementations, upon failing to successfully decode the sensed data based on the hard bits, the memory sub-system may employ soft-decision decoding, which may take into account “soft” input information (alongside a hard input value) indicating the reliability of a hard value determination (e.g., a confidence level or likelihood that a particular bit-value is in fact ‘0’ or ‘1’). Thus, a memory sub-system, in retrieving a stored codeword, may perform a read operation that not only returns a hard value as a series of hard bits, but also a series of one or more “soft bits” for each hard bit, which may indicate a reliability of a particular hard bit determination.

A read operation may measure the threshold voltage of a target memory cell of a set of memory cells. By comparing the measured threshold voltage value to the estimated threshold voltage distributions associated with the set of memory cells, the read operation may return a predefined number of “soft bits” of information for each “hard” bit. Soft-decision decoding may be described in terms of the number of hard bits (H) and soft bits (S) that are provided as input to the decoder (e.g., 1H2S, 1H3S, etc.).

In an illustrative example, a memory sub-system may perform a read operation that returns an estimated threshold voltage value for a particular memory cell. The voltage value may fall within one of a predefined plurality of decoder input bins. Each decoder input bin may be associated with a predefined sequence of bit values, including one hard bit value and one or more soft bit values. For example, the memory sub-system may perform a read operation that returns three soft bits of information for each hard bit, with ‘000’ indicating the highest level of reliability and ‘111’ indicating the lowest level of reliability in the hard bit determination.

The combination of the hard bit and the soft bits may be converted into a likelihood value, which reflects the probability that the memory cell will be decoded as a specific binary value (e.g., “1”). In other words, the combination of the hard bit and one or more corresponding soft bits may be translated into a likelihood value that reflects the probability of the memory cell (having its threshold voltage within a decoder input bin that is identified by the combination of the hard bit and the corresponding soft bits) to be decoded as a particular binary value (e.g., “1”).

In some implementations, the likelihood value may be represented by the log likelihood ratio (LLR):

$$LLR ( bit i ) = log ( \frac{P ( bit i = 0 \vert read info}{P ( bit i = 1 \vert read info} ) ,$$

where i is the identifier of the bit (the memory cell for SLC), read info is the information read from the memory device (i.e., the combination of the hard bit and its corresponding soft bits), P(bit i=0|read info) is the probability of bit i be decoded as 0 based on the information read from the memory device (i.e., the combination of the hard bit and its corresponding soft bits), and P(bit i=1|read info) is the probability of bit i be decoded as 1 based on the information read from the memory device (i.e., the combination of the hard bit and its corresponding soft bits).

In some implementations, converting the combination of the hard bit and the soft bits into a corresponding LLR value may be performed using a look-up table (LUT), which may map various possible combinations of the hard bit and soft bits into corresponding LLR values. The LUT may be pre-computed by the manufacturer of the memory sub-system and stored in the metadata area of a memory device. The memory sub-system may then provide the LLR values corresponding to the sensed data returned by a read operation to an LDPC decoder, which may attempt to decode the sensed data.

While, soft-decision decoding, in general, provide for relatively better error correction as compared to hard-decision decoding techniques, they tend to be more expensive to implement. For example, as noted above, soft-decision decoding involves more complicated and time-consuming read operations (e.g., to obtain the desired reliability information), thereby utilizing higher power and/or more complex decoding circuitry among other issues.

Aspects of the present disclosure address the above and other deficiencies by having a memory sub-system that utilizes read operations of ARC to obtain LLR values to be used in soft-decision decoding. In particular, during each read voltage adjustment of a predetermined number of read voltage adjustments of ARC, a current read voltage level is obtained based on adjustments to a previous read volage level by a predetermined amount. The ARC performs a read operation using the current read voltage level to obtain a current sensed data which reflects the encoded host data read at the current read voltage level. Once the current sensed data is obtained, a previous sensed data may be retrieved from local memory to be used in an exclusive-OR (XOR) operation to determine whether at least one bit has flipped from the previous sensed data to the current sensed data. The previous sensed data reflects the encoded host data read during a previous read operation at a previous read volage level.

Determining whether at least one bit has flipped in the current sensed data since the previous sensed data includes determining whether at least one bit of the result of the XOR operation has a bit value of ‘1’ indicating a difference between a bit of the current sensed data and a corresponding bit of the previous sensed data. The flipped bits are identified from the result of the XOR operation by identifying a position of each bit of the result of the XOR having a bit value of ‘1.’ An LLR value to assign to the flipped bits is determined based on a position of a region established by the current read voltage level and the previous read voltage level to an optimal read voltage level. For example, the closer the region is to the optimal read voltage level the smaller the magnitude of the LLR value, and the further the region is from the optimal read voltage level the larger the optimal read voltage level. Further, for example, if the region is to the left of the optimal read voltage level the LLR value is assigned a negative sign, otherwise the LLR value is assigned a positive sign. Accordingly, the LLR value to be assigned to the flipped bits are identified from the position of the region established by the current read voltage level and the previous read voltage level.

The LLR value is assigned to the flipped bits by updating each entry of an LLR assignment table associated with the flipped bits. More specifically, each entry of the LLR assignment corresponds to a position of a bit in the sensed data and includes an assigned LLR value. Thus, each entry is identified using a position associated with the flipped bits and updated with the LLR value to reflect the assigned LLR value. Once the predetermined number of read voltage adjustments of the ARC is reached, the assigned LLR values from the LLR assignment table is used by an LDPC decoder for soft-decision decoding to decode the sensed data.

Advantages of the present disclosure include, but are not limited to, improved performance in the memory sub-system. The techniques described herein can reduce latency, and increase the efficiency of the error handling sequence, thereby improving read performance, quality of service (QoS), and reliability of the memory device.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

The memory sub-system 110 includes an error handling component 113 that can utilizes read operations of an auto read calibration to obtain LLR values to be used in a soft-decision decoding. In some embodiments, the memory sub-system controller 115 includes at least a portion of the error handling component 113. In some embodiments, the error handling component 113 is part of the host system 120, an application, or an operating system. In other embodiments, local media controller 135 includes at least a portion of error handling component 113 and is configured to perform the functionality described herein.

In some implementations, memory sub-system 110 may receive a request from the host system 120 to read host data that was previously encoded and stored in memory device 130 and/or 140. In response to the request, memory sub-system 110 may perform a read operation to read the encoded host data from memory device 130 and/or 140. The encoded host data read back from the memory device 130 and/or 140 (or sensed data) may comprise one or more sensed codewords.

The sensed data may be decoded by a decoder of the memory sub-system 110 to obtain the host data encoded. In some instances, the sensed data read back from the memory device may differ from the initial encoded data that was first generated, for example, on account of errors (e.g., bit-flip errors) that may have occurred during storage and/or retrieval of the encoded data to/from the memory device. The ECC used to encode the host data may be used to recover the original host data. In particular, the ECC detects and attempts to correct any errors in the sensed data.

In the event the decoder of the memory sub-system 110 is unable to correct the errors in the sensed data, the error handling component 113 attempts to recover the original host data from the sensed data. More specifically, the error handling component 113 may perform a sequence of error handling operations (or error handling sequence). For example, the error handling sequence can include one or more read retries, coarse threshold estimation (CTE), auto read calibration (ARC), and soft-decision decoding (e.g., 1 hard bits (H)/2 soft bits (S) (1H2S)). Depending on the embodiment, the error handling sequence can include at least the ARC and soft-decision decoding.

In some implementations, the ARC attempts to recover the original host data from the sensed data by determining a valley (e.g., a target) associated with a programming level distribution. The ARC iteratively performs read operations for a predetermined number of read voltage adjustments. Each read voltage adjustment of the ARC, a read voltage level is adjusted by a predetermined amount to identify an optimal or ideal read voltage level for the target by moving the read voltage closer to the target in a stepwise approach.

Upon initiating the ARC in the error handling sequence, the error handling component 113 adjusts a previous read volage level during each read voltage adjustment of the ARC. The previous read volage level is adjusted by a predetermined amount to obtain a current read voltage level. A read operation is performed with the current read voltage level. The error handling component 113 obtains, from the read operation with the current read voltage level, a current sensed data. The current sensed data reflects the encoded host data read at the current read voltage level.

The error handling component 113 retrieves, from local memory 119, a previous sensed data. Each sensed data obtained from any read operation of any error handling operation of the error handling sequence can be maintained and stored in local memory 119. The previous sensed data reflects the encoded host data read during a previous read operation at a previous read volage level. The previous read voltage level is a read voltage level prior to a current read voltage level obtained from a current read voltage adjustment of the ARC.

The error handling component 113 may determine whether at least one bit has flipped in the current sensed data since the previous sensed data. In other words, has the current data voltage level caused at least one bit to flip when compared to the previous sensed data. In some embodiments, to determine whether at least one bit has flipped in the current sensed data, the error handling component 113 performs an exclusive-OR (XOR) operation on the current sensed data and the previous sensed data.

The error handling component 113, based on a result of the XOR operation, determines whether at least one bit has flipped. More specifically, the error handling component 113 determines whether at least one bit of the result of the XOR operation has a bit value of ‘1’ which indicates a difference between a bit of the current sensed data and a corresponding bit of the previous sensed data.

Responsive to determining that at least one bit of the result of the XOR operation has a bit value of ‘1,’ the error handling component 113 identifies each bit of the current sensed data was flipped by identifying a position of each bit of the result of the XOR having a bit value of ‘1’ (e.g., the flipped bits). For example, if an XOR operation is performed on the current sensed data (e.g., 10111010) and the previous sensed data (e.g., 10101010), the result of the XOR operation is (e.g., 00010000). The error handling component 113 determines that a fourth bit of the result of the XOR operation has a bit value of ‘1,’ which indicates that the fourth bit of the current sensed data has been flipped (e.g., the flipped bit).

The error handling component 113 identifies an LLR value to assign to the flipped bit of the current sensed data. The error handling component 113 identifies, among a plurality of read voltage levels, an optimal read voltage level. The plurality of read voltage levels includes at least the current read voltage level and the previous read voltage level. In some embodiments, the plurality of read voltage levels may include additional read voltage levels that were previously used to perform the read operation. Each pair of adjacent read voltage levels of the plurality of read voltage levels establishes a region. Accordingly, the plurality of read voltage levels (t number of read voltage levels) may establish a plurality of regions (t-1 number of regions). Based on the read voltage level of the plurality of read voltage levels identified as the optimal read voltage level, each region may be assigned an LLR values with a specific magnitude. For example, the closer a region is to the optimal read voltage level the smaller the assigned magnitude of the LLR value and the further a region is from the optimal read voltage level the larger the assigned magnitude of the LLR value.

Additionally, given that the optimal read voltage level indicates that any cell with a threshold voltage less than (or to the left of) the optimal read voltage level is interpreted as “1” and any cell with a threshold voltage greater than (or to the right of) the optimal read voltage level is interpreted as “0.” A subset of regions of the plurality of regions to the left of the optimal read voltage level results in a first sign (e.g., a negative sign) applied to the magnitude of the LLR value assigned to each region of the subset of regions of the plurality of regions to the left of the optimal read voltage level. Otherwise, a subset of regions of the plurality of regions to the right of the optimal read voltage level results in a second sign (e.g., a positive sign) applied to the magnitude of the LLR value assigned to each region of the subset of regions of the plurality of regions to the right of the optimal read voltage level. The error handling component 113 identifies the region associated with the current read voltage level and the previous read voltage level and obtains the LLR value assigned to the region.

The error handling component 113 updates one or more entries of an LLR assignment table (or LLR assignment data structure) associated with the flipped bits with the obtained LLR value. The error handling component 113 may maintain the LLR assignment table in local memory 119, for example. The LLR assignment table includes a plurality of entries. Each entry of the LLR assignment table is identified by a position of the bit in the sensed data and includes an assigned LLR value. For example, for an 8-bit byte of sensed data, a first entry of the LLR assignment table corresponds to a first bit of the sensed data, a second entry of the LLR assignment table corresponds to a second bit of the sensed data, and so on. Accordingly, the error handling component 113 identifies each entry to update based on the flipped bits. The error handling component 113 updates, the assigned LLR value of each entry, with the retrieved LLR value.

Once the predetermined number of read voltage adjustments of the ARC is reached, the error handling component 113 may determine that the ARC is complete and proceed to the soft-decision decoding. During the soft-decision decoding, the error handling component 113 may provide the LLR values from the LLR assignment table to an LDPC decoder of the soft-decision decoding to attempt to decode the sensed data. Further details with regards to the operations of the error handling component 113 are described below.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device. In one embodiment, memory sub-system controller 115 includes error handling component 113 configured to utilize read operations of ARC to obtain LLR values to be used in a soft-decision decoding.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bit line). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data may be passed from the cache register 172 to the data register 170 for transfer to the array of memory cells 104; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer of the memory device 130. A page buffer may further include sensing devices (not shown in FIG. 1B) to sense a data state of a memory cell of the array of memory cells 104, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 132. For example, the control signals can include a chip enable signal CE #, a command latch enable signal CLE, an address latch enable signal A L E, a write enable signal WE #, a read enable signal RE #, and a write protect signal WP #. Additional or alternative control signals (not shown) may be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 236 and outputs data to the memory sub-system controller 115 over I/O bus 236.

For example, the commands may be received over input/output (I/O) pins [7:0] of I/O bus 236 at I/O control circuitry 160 and may then be written into command register 124. The addresses may be received over input/output (I/O) pins [7:0] of I/O bus 236 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the array of memory cells 104.

In an embodiment, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

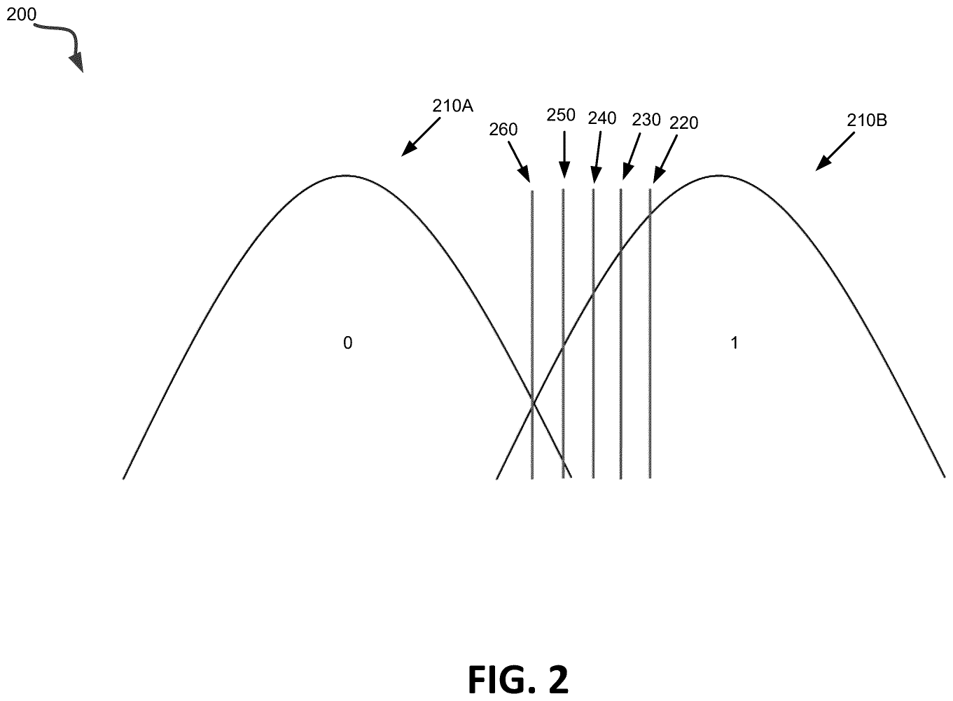

FIG. 2 is a diagram illustrating an auto read calibration operation on programming voltage distributions for an SLC 200 in accordance with some embodiments of the present disclosure. The programming voltage distributions for SLC 200 includes a peak 210A representing a binary value of ‘0’ and a peak 210B representing a binary value of ‘1.’ A read voltage level is essential in correctly interpreting the data stored in the SLC as either 0 or 1. In order to correctly interpreting the data stored in the SLC the read voltage level must be set to a value that falls between the peak 210A and 210B (e.g., a valley).

During read error handling, initiated in response to a decoder failing to correct errors in sensed data, ARC of the read error handling can be used to recover the original host data from the sensed data by determining the valley. The ARC performs a read operation to read the encoded host data with a read voltage level 220. The error handling component 113 of FIG. 1 may determine that a previous read operation was not performed during ARC, thus ARC can proceed to determine that the data state metrics of the sensed data obtained from performing the read operation with the read voltage level 220 indicates that the initial read voltage level 220 is not in the valley.

The ARC may adjust the read voltage level 220, in response to a read level adjustment of a plurality of read level adjustments, by a predetermined amount to obtain read voltage level 230. The ARC may perform another read operation with read voltage level 230. The error handling component 113 may determine that a previous read operation was performed during ARC, thus the error handling component 113 determines, based on the read operations performed using read voltage level 220 and read voltage level 230, an LLR value to assign to one or more bits of the sensed data. In particular, the error handling component 113 performs an exclusive-OR (XOR) operation on the sensed data obtained using the read voltage level 220 (sensed data of read voltage level 220) and the sensed data obtained using the read voltage level 230 (e.g., sensed data of read voltage level 230). The result of the XOR operation indicates one or more bits that were flipped from the sensed data of read voltage level 220 to the sensed data of read voltage level 230 (e.g., flipped bits). Depending on whether read voltage level 220 is identified as the optimal read voltage level or read voltage level 230, a region between read voltage level 220 and read voltage level 230 is assigned an LLR value with a small magnitude. If read voltage level 220 is identified as the optimal read voltage level, then the LLR value assigned to the region between read voltage level 220 and read voltage level 230 is negative. Otherwise, if read voltage level 230 is identified as the optimal read voltage level, then the LLR value assigned to the region between read voltage level 220 and read voltage level 230 is positive. The error handling component 113 assigns the LLR value assigned to the region, to the flipped bits. The error handling component 113, based on the flipped bits, stores in one or more entries of an LLR assignment table the LLR value.

The data state metrics associated with sensed data of read voltage level 230 indicates that the read voltage level 230 is not in the valley. The ARC may adjust the read voltage level 230, in response to a subsequent read level adjustment of the plurality of read level adjustments, by the predetermined amount to obtain read voltage level 240. The ARC may perform another read operation with read voltage level 240. The error handling component 113 may determine that a previous read operation was performed during ARC, thus the error handling component 113 performs an XOR operation on the sensed data obtained using the read voltage level 230 (e.g., sensed data of read voltage level 230) and the sensed data obtained using the read voltage level 240 (e.g., sensed data of read voltage level 240). The error handling component 113 identifies, from the result of the XOR operation, the flipped bits.

Depending on whether read voltage level 220, read voltage level 230, or read voltage level 240 is identified as the optimal read voltage level, each region of a plurality of regions (e.g., region between read voltage level 220 and read voltage level 230 and region between read voltage level 230 and read voltage level 240) is assigned an LLR value with an appropriate magnitude and sign. For example, the closer the region is to the read voltage level designated as the optimal read voltage level, the smaller the magnitude of the LLR value assigned to the respective region, and the further the region is from the read voltage level designated as the optimal read voltage level the larger the magnitude of the LLR value assigned to the respective region. Additionally, each region positioned to the right of the read voltage level designated as the optimal read voltage level is a positive LLR value, and each region positioned to the left of the read voltage level designated as the optimal read voltage level is a negative LLR value. Thus, the error handling component 113 identifies the region of the plurality of regions established by the read voltage level 230 and the read voltage level 240 and obtains the LLR value assigned to the region to the flipped bits. The error handling component 113, based on the flipped bits, stores in one or more entries of an LLR assignment table the LLR value.

The data state metrics associated with sensed data of read voltage level 240 indicates that the read voltage level 240 is not in the valley. The ARC may adjust the read voltage level 240, in response to a subsequent read level adjustment of the plurality of read level adjustments, by the predetermined amount to obtain read voltage level 250. The ARC may perform another read operation with read voltage level 250. The error handling component 113 may determine that a previous read operation was performed during ARC, thus the error handling component 113 performs an XOR operation on the sensed data obtained using the read voltage level 240 (e.g., sensed data of read voltage level 240) and the sensed data obtained using the read voltage level 250 (e.g., sensed data of read voltage level 250). The error handling component 113 identifies, from the result of the XOR operation, the flipped bits.

Depending on whether read voltage level 220, read voltage level 230, read voltage level 240 or read voltage level 250 is identified as the optimal read voltage level, each region of a plurality of regions (e.g., region between read voltage level 220 and read voltage level 230, region between read voltage level 230 and read voltage level 240, and region between read voltage level 240 and read voltage level 250) is assigned an LLR value with an appropriate magnitude and sign. For example, the closer the region is to the read voltage level designated as the optimal read voltage level, the smaller the magnitude of the LLR value assigned to the respective region, and the further the region is from the read voltage level designated as the optimal read voltage level the larger the magnitude of the LLR value assigned to the respective region. Additionally, each region positioned to the right of the read voltage level designated as the optimal read voltage level is a positive LLR value, and each region positioned to the left of the read voltage level designated as the optimal read voltage level is a negative LLR value. Thus, the error handling component 113 identifies the region of the plurality of regions established by the read voltage level 240 and the read voltage level 250 and obtains the LLR value assigned to the region to the flipped bits. The error handling component 113, based on the flipped bits, stores in one or more entries of an LLR assignment table the LLR value. The error handling component 113, based on the flipped bits, stores in one or more entries of an LLR assignment table the LLR value.

The data state metrics associated with sensed data of read voltage level 250 indicates that the read voltage level 250 is not in the valley. The ARC may adjust the read voltage level 250, in response to a subsequent read level adjustment of the plurality of read level adjustments, by the predetermined amount to obtain read voltage level 260. The ARC may perform another read operation with read voltage level 260. The error handling component 113 may determine that a previous read operation was performed during ARC, thus the error handling component 113 performs an XOR operation on the sensed data obtained using the read voltage level 250 (e.g., sensed data of read voltage level 250) and the sensed data obtained using the read voltage level 260 (e.g., sensed data of read voltage level 260). The error handling component 113 identifies, from the result of the XOR operation, the flipped bits.

Depending on whether read voltage level 220, read voltage level 230, read voltage level 240, read voltage level 250, or read voltage level 260 is identified as the optimal read voltage level, each region of a plurality of regions (e.g., region between read voltage level 220 and read voltage level 230, region between read voltage level 230 and read voltage level 240, region between read voltage level 240 and read voltage level 250, and region between read voltage level 250 and read voltage level 260) is assigned an LLR value with an appropriate magnitude and sign. For example, the closer the region is to the read voltage level designated as the optimal read voltage level, the smaller the magnitude of the LLR value assigned to the respective region, and the further the region is from the read voltage level designated as the optimal read voltage level the larger the magnitude of the LLR value assigned to the respective region. Additionally, each region positioned to the right of the read voltage level designated as the optimal read voltage level is a positive LLR value, and each region positioned to the left of the read voltage level designated as the optimal read voltage level is a negative LLR value. Thus, the error handling component 113 identifies the region of the plurality of regions established by the read voltage level 250 and the read voltage level 260 and obtains the LLR value assigned to the region to the flipped bits. The error handling component 113, based on the flipped bits, stores in one or more entries of an LLR assignment table the LLR value. The error handling component 113, based on the flipped bits, stores in one or more entries of an LLR assignment table the LLR value. The error handling component 113, based on the flipped bits, stores in one or more entries of an LLR assignment table the LLR value. The data state metrics associated with sensed data of read voltage level 260 indicates that the read voltage level 250 is in the valley and terminates the ARC.

In some embodiments, a plurality of read operations are performed during the ARC for each read level adjustment of the plurality of read level adjustments of the ARC. Accordingly, once a last read operation associated with a last read level adjustment of the plurality of read level adjustments is performed, the ARC may be terminated. The error handling component 113 may proceed to soft-decision decoding of the read error handling and utilize the LLR values stored in the LLR assignment table.

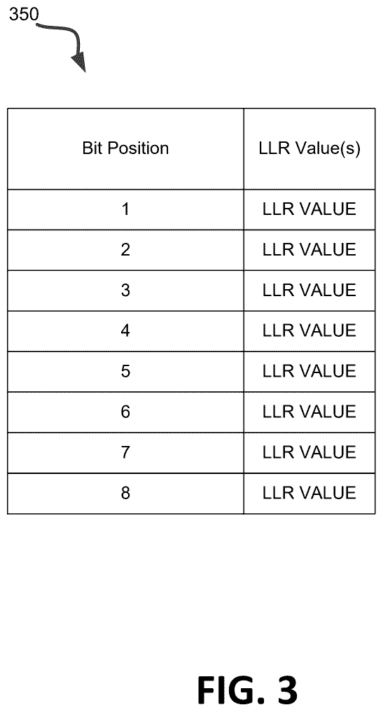

FIG. 3 illustrates an example of a LLR assignment data structure (e.g., table) 350 that stores each LLR value assigned to a bit of the sensed data obtained during ARC, in accordance with some embodiments of the present disclosure. In one embodiment, the LLR assignment data structure is stored in local memory 119 of the memory sub-system 110.

The LLR assignment structure 350 includes a plurality of entries. Each entry of the LLR assignment structure 350 is identified by a bit position (e.g., Bit 1-7 for an 8-bit byte of sensed data). Each entry includes an LLR value to be assigned to a bit position of the sensed data (e.g., a respective bit of the sensed data).

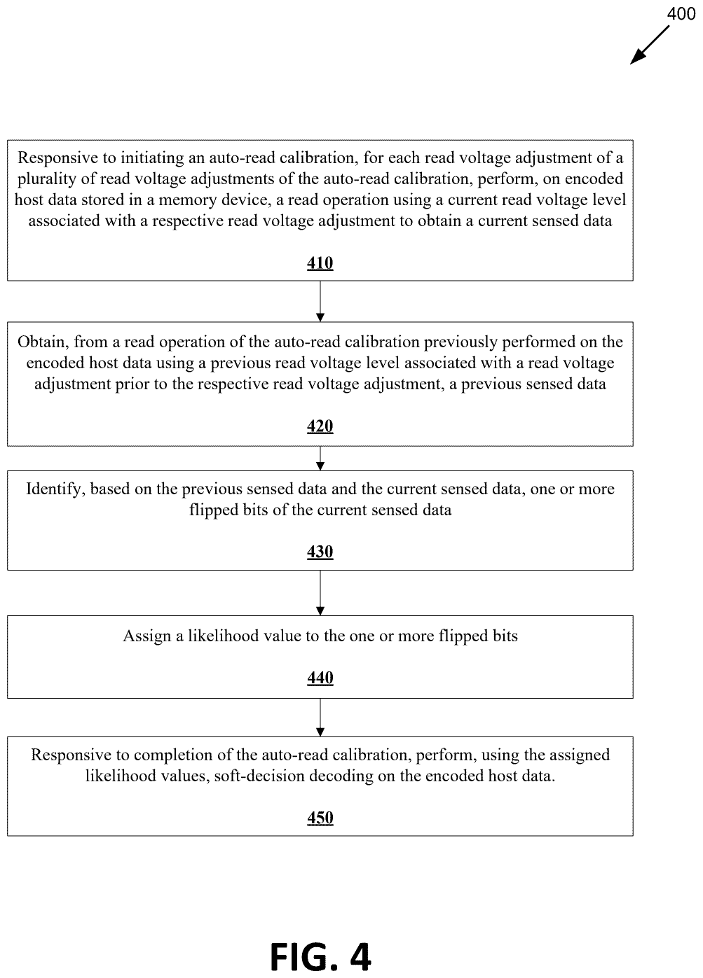

FIG. 4 is a flow diagram of an example method 400 to reducing read operations during read error handling in a memory device, in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by the error handling component 113 of FIG. 1A. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 410, responsive to initiating an auto-read calibration comprising a plurality of read voltage adjustments, the processing logic performs a plurality of read operations on encoded host data stored in a memory device using the plurality of read voltage level adjustments to obtain current sensed data.

As previously described, the auto-read calibration is initiated in response to a decoder being unable to correct the errors in a sensed data. The auto-read calibration (ARC) may be part of a read error handling which may include additional steps, such as a soft-decision decoding subsequent to the ARC. The ARC, as previously described, iteratively performs read operations for a predetermined number of read voltage adjustments. Each read voltage adjustment of the plurality of read voltage adjustments of the auto-read calibration produces a read voltage level by applying a predetermined amount of adjustment to a read voltage level used to perform a previous read operation. In other words, as previously described, each read voltage adjustment of the ARC, a read voltage level is adjusted by a predetermined amount to identify an optimal or ideal read voltage level for the target by moving the read voltage closer to the target in a stepwise approach.

At operation 420, the processing logic obtains, from a previous one of the plurality of read operations performed on the encoded host data using a previous read voltage level adjustment, a previous sensed data. As previously described, the previous sensed data may be retrieved from local memory. That is, each sensed data obtained from any read operation of ARC can be maintained and stored in local memory.

At operation 430, the processing logic identifies, based on the previous sensed data and the current sensed data, one or more flipped bits of the current sensed data. In particular, the processing logic performs an exclusive OR (XOR) operations on the previous sensed data and the current sensed data. The processing logic identifies, based on a result of the XOR operation, each bit of the current sensed data that were flipped as the one or more flipped bits of the current sensed data. Each bit of the result having a bit value of 1 indicates that a corresponding bit of the current sensed data was flipped from the previous sensed data. In other words, each position of a bit of the result having a bit value of 1 provides a position of the bits flipped in the sensed data (e.g., the one or more flipped bits).

At operation 440, the processing logic assigns a likelihood value to the one or more flipped bits. The processing logic, to assign the likelihood value (e.g., LLR value) to the one or more flipped bits, obtains a likelihood value based on a position of a region between the current read voltage level and the previous read voltage level to an optimal read voltage level. The position of the region between the current read voltage level and the previous read voltage level to the optimal read voltage level may indicate the magnitude of the likelihood value and the sign of the likelihood value. As previously described, the closer the region is to the optimal read voltage level the smaller the magnitude of the LLR value and the further a region is from the optimal read voltage level the larger the magnitude of the LLR value. If the region is positioned to the left of the optimal read voltage level the LLR value is negative, and if the region is positioned to the right of the optimal read voltage level the LLR value is positive.

The processing logic identifies, based on the encoded host data, a likelihood assignment data structure (e.g., the LLR assignment table) associated with the encoded host data. E ach entry of the LLR assignment data structure corresponds to a position of a bit of the encoded host data. For each bit of the flipped bits, the processing logic stores, in an entry of the LLR assignment data structure corresponding to a position associated with a respective bit of the flipped bits, the obtained likelihood value. As previously described, the LLR assignment table, maintained in local memory, includes a plurality of entries each of which is identified by a position of the bit in encoded host data and includes an assigned LL R value.

At operation 450, responsive to completion of the auto-read calibration, the processing logic performs, using the assigned likelihood values of the likelihood assignment data structure (or LL R values of the LLR assignment table), soft-decision decoding on the encoded host data. The completion of the auto-read calibration is determined by one of performing a read operation using a read voltage level obtained by each read voltage adjustment of the plurality of read voltage adjustments of the auto-read calibration or obtaining a read voltage level between a pair of logical states.

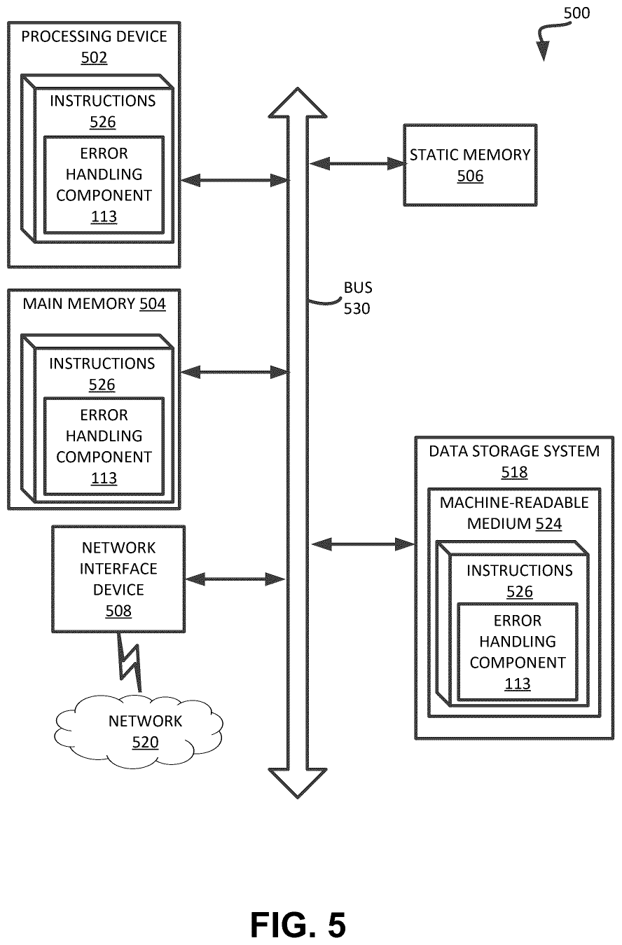

FIG. 5 illustrates an example machine of a computer system 500 within which a set of instructions, for causing the machine to perform any one or more of the methodologies discussed herein, can be executed. In some embodiments, the computer system 500 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the error handling component 113 of FIG. 1A). In alternative embodiments, the machine can be connected (e.g., networked) to other machines in a LA N, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM) or RDRAM, etc.), a static memory 506 (e.g., flash memory, static random access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 426 for performing the operations and steps discussed herein. The computer system 500 can further include a network interface device 508 to communicate over the network 420.

The data storage system 518 can include a machine-readable storage medium 424 (also known as a computer-readable medium) on which is stored one or more sets of instructions 426 or software embodying any one or more of the methodologies or functions described herein. The instructions 426 can also reside, completely or at least partially, within the main memory 504 and/or within the processing device 502 during execution thereof by the computer system 500, the main memory 504 and the processing device 502 also constituting machine-readable storage media. The machine-readable storage medium 424, data storage system 518, and/or main memory 504 can correspond to the memory sub-system 110 of FIG. 1A.

In one embodiment, the instructions 526 include instructions to implement functionality corresponding to an error handling component (e.g., the error handling component 113 of FIG. 1A). While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. A n algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
responsive to initiating an auto-read calibration operation comprising a plurality of read voltage level adjustments, performing a plurality of read operations on encoded host data stored in a memory device using the plurality of read voltage level adjustments to obtain current sensed data;
obtaining, from a previous one of the plurality of read operations performed on the encoded host data using a previous read voltage level adjustment, a previous sensed data;
identifying, based on the previous sensed data and the current sensed data, one or more flipped bits of the current sensed data;
assigning a likelihood value to the one or more flipped bits; and
responsive to completion of the auto-read calibration, performing, using the assigned likelihood value, soft-decision decoding on the encoded host data.

2. The method of claim 1, wherein identifying, based on the previous sensed data and the current sensed data, the one or more flipped bits of the current sensed data comprises:
performing an exclusive OR (XOR) operations on the previous sensed data and the current sensed data; and
identifying, based on a result of the XOR operation, each bit of the current sensed data that were flipped as the one or more flipped bits of the current sensed data.

3. The method of claim 2, wherein each bit of the result having a bit value of 1 indicates that a corresponding bit of the current sensed data was flipped.

4. The method of claim 1, wherein assigning the likelihood value to the one or more flipped bits comprises:
obtaining a likelihood value based on a position of a region between the current read voltage level and the previous read voltage level to an optimal read voltage level;
identifying, based on the encoded host data, a likelihood assignment data structure associated with the encoded host data, wherein each entry of the likelihood assignment data structure corresponds to a position of a bit of the encoded host data; and
for each bit of the flipped bits, storing, in an entry of the likelihood assignment data structure corresponding to a position associated with a respective bit of the flipped bits, the obtained likelihood value.

5. The method of claim 4, wherein the position of the region between the current read voltage level and the previous read voltage level to the optimal read voltage level indicates a magnitude of the likelihood value and a sign of the likelihood value.

6. The method of claim 1, wherein each read voltage adjustment of the plurality of read voltage adjustments of the auto-read calibration produces a read voltage level by applying a predetermined amount of adjustment to a read voltage level used to perform a previous read operation.

7. The method of claim 1, wherein the completion of the auto-read calibration is determined by one of: performing a read operation using a read voltage level obtained by each read voltage adjustment of the plurality of read voltage adjustments of the auto-read calibration or obtaining a read voltage level between a pair of logical states.

8. A system comprising:
a plurality of memory devices; and
a processing device, operatively coupled with the plurality of memory devices, to perform operations comprising:
responsive to initiating an auto-read calibration operation comprising a plurality of read voltage level adjustments, performing a plurality of read operations on encoded host data stored in a memory device of the plurality of memory devices using the plurality of read voltage level adjustments to obtain current sensed data;
obtaining, from a previous one of the plurality of read operations performed on the encoded host data using a previous read voltage level adjustment, a previous sensed data;
identifying, based on the previous sensed data and the current sensed data, one or more flipped bits of the current sensed data;
assigning a likelihood value to the one or more flipped bits; and
responsive to completion of the auto-read calibration, performing, using the assigned likelihood value, soft-decision decoding on the encoded host data.

9. The system of claim 8, wherein identifying, based on the previous sensed data and the current sensed data, the one or more flipped bits of the current sensed data comprises:
performing an exclusive OR (XOR) operations on the previous sensed data and the current sensed data; and
identifying, based on a result of the XOR operation, each bit of the current sensed data that were flipped as the one or more flipped bits of the current sensed data.

10. The system of claim 9, wherein each bit of the result having a bit value of 1 indicates that a corresponding bit of the current sensed data was flipped.

11. The system of claim 8, wherein assigning the likelihood value to the one or more flipped bits comprises:
obtaining a likelihood value based on a position of a region between the current read voltage level and the previous read voltage level to an optimal read voltage level;
identifying, based on the encoded host data, a likelihood assignment data structure associated with the encoded host data, wherein each entry of the likelihood assignment data structure corresponds to a position of a bit of the encoded host data; and
for each bit of the flipped bits, storing, in an entry of the likelihood assignment data structure corresponding to a position associated with a respective bit of the flipped bits, the obtained likelihood value.

12. The system of claim 11, wherein the position of the region between the current read voltage level and the previous read voltage level to the optimal read voltage level indicates a magnitude of the likelihood value and a sign of the likelihood value.

13. The system of claim 8, wherein each read voltage adjustment of the plurality of read voltage adjustments of the auto-read calibration produces a read voltage level by applying a predetermined amount of adjustment to a read voltage level used to perform a previous read operation.

14. The system of claim 8, wherein the completion of the auto-read calibration is determined by one of: performing a read operation using a read voltage level obtained by each read voltage adjustment of the plurality of read voltage adjustments of the auto-read calibration or obtaining a read voltage level between a pair of logical states.

15. A non-transitory computer-readable storage medium comprising instructions that, when executed by a processing device, cause the processing device to perform operations comprising:
responsive to initiating an auto-read calibration operation comprising a plurality of read voltage level adjustments, performing a plurality of read operations on encoded host data stored in a memory device using the plurality of read voltage level adjustments to obtain current sensed data;
obtaining, from a previous one of the plurality of read operations performed on the encoded host data using a previous read voltage level adjustment, a previous sensed data;
identifying, based on the previous sensed data and the current sensed data, one or more flipped bits of the current sensed data;
assigning a likelihood value to the one or more flipped bits; and
responsive to completion of the auto-read calibration, performing, using the assigned likelihood value, soft-decision decoding on the encoded host data.

16. The non-transitory computer-readable storage medium of claim 15, wherein identifying, based on the previous sensed data and the current sensed data, the one or more flipped bits of the current sensed data comprises:
performing an exclusive OR (XOR) operations on the previous sensed data and the current sensed data; and
identifying, based on a result of the XOR operation, each bit of the current sensed data that were flipped as the one or more flipped bits of the current sensed data.

17. The non-transitory computer-readable storage medium of claim 16, wherein each bit of the result having a bit value of 1 indicates that a corresponding bit of the current sensed data was flipped.

18. The non-transitory computer-readable storage medium of claim 15, wherein assigning the likelihood value to the one or more flipped bits comprises:
obtaining a likelihood value based on a position of a region between the current read voltage level and the previous read voltage level to an optimal read voltage level;
identifying, based on the encoded host data, a likelihood assignment data structure associated with the encoded host data, wherein each entry of the likelihood assignment data structure corresponds to a position of a bit of the encoded host data; and
for each bit of the flipped bits, storing, in an entry of the likelihood assignment data structure corresponding to a position associated with a respective bit of the flipped bits, the obtained likelihood value.

19. The non-transitory computer-readable storage medium of claim 18, wherein the position of the region between the current read voltage level and the previous read voltage level to the optimal read voltage level indicates a magnitude of the likelihood value and a sign of the likelihood value.

20. The non-transitory computer-readable storage medium of claim 15, wherein each read voltage adjustment of the plurality of read voltage adjustments of the auto-read calibration produces a read voltage level by applying a predetermined amount of adjustment to a read voltage level used to perform a previous read operation.
